(19) United States
(12) Patent Application Publication
(10) Pub. No.: US 2014/0183744 A1
(43) Pub. Date: Jul. 3, 2014

(54) PACKAGE SUBSTRATE WITH BONDABLE TRACES HAVING DIFFERENT LEAD FINISHES

(71) Applicant: TEXAS INSTRUMENTS INCORPORATED, Dallas, TX (US)

(72) Inventor: MYUNGHO LEE, GWANGJU (KR)

(73) Assignee: TEXAS INSTRUMENTS INCORPORATED, Dallas, TX (US)

(21) Appl. No.: 13/730,048

(22) Filed: Dec. 28, 2012

(51) Int. Cl. H01L 23/532

(52) U.S. Cl. CPC H01L 23/532
USPC 257/762

(57) ABSTRACT

A package substrate includes a workpiece having at least a top dielectric layer and a metal layer thereon which provides a plurality of metal traces on a surface of the top dielectric layer. A first solder resist layer provides covered trace portions of the plurality of metal traces. A second solder resist layer on the first solder resist layer defines an inner die attach region. The die attach region includes exposed trace portions of the metal traces. The exposed trace portions each include (i) a bonding area having a base metal and a metal or metal alloy surface finish thereon for bonding to bonding features of an integrated circuit (IC) die, and (ii) an interconnect trace portion on both sides of the bonding area including the base metal having a second surface finish thereon different from the metal or metal alloy surface finish.

### FIELD

Disclosed embodiments relate to package substrates and packaging of semiconductor devices, and more specifically to package substrates having dielectric substrates with metal traces that have surface layers and packaged semiconductor devices therefrom.

### BACKGROUND

The flip chip (FC) package is an advanced packaging technique for connecting an integrated circuit (IC) die to a substrate (e.g., a lead frame or a printed circuit board (PCB)). During the packaging process, the IC die is assembled top side (circuit side) down to connect its bonding features (e.g., solder balls or pillars) that are generally on die pads to pads on the substrate.

In the case of a package substrate, the substrate is commonly a dielectric material with two sides, one side having a first metal interconnect layer including bond pads and the other side with a second metal interconnect layer. The first and the second metal interconnect layers are electrically connected by a plurality of vias. The top surface of the substrate generally includes a dielectric solder mask material in areas outside the bond pads. The solder mask over conventional copper traces prevents copper oxidation, masks against solder spreading around the solder joints, and provides enhanced adhesion to underfill. The top side of the IC die has a plurality of die pads. Under bump metallurgy (UBM) is generally formed on the die pad surface before forming the bumps thereon.

The flipped IC die is generally bonded by soldering or an ultrasonic process (e.g. in the cases of Au—Au) to the bond pads of the first metal interconnect layer of the substrate (referred to as FC pads) through the bumps or pillars on the IC die surface to form “solder joints”. Then an underfill layer is formed in the gap region between the IC die and the substrate. Underfill generally comprises a dielectric polymer material, such as a silica-filled epoxy resin. The function of the underfill is to reduce the stress in the solder joints caused by the coefficient of thermal expansion (CTE) mismatch, and to cover all traces to avoid solder wicking during the solder reflow process.

As the IC die become both smaller for higher performance with advancements in silicon node generations (90 nm, 65 nm, 45 nm, and beyond), the need for fine-pitch FC technology can become important in providing a semiconductor package that meets the electrical, thermal, and dimensional requirements of the application. With higher device performance comes higher input/output (I/O) count, which when coupled with IC size reduction creates the need for fine-pitch FC technology.

### SUMMARY

Disclosed embodiments include package substrates having metal traces which provide bonding areas for bonding features of an integrated circuit (IC) die thereto and an interconnect trace portion on both sides of the bonding area which provides protection from solder shorting between neighboring metal traces. The bonding area has a base metal and a metal or metal alloy surface finish thereon, and the interconnect trace portion includes the base metal having a surface finish thereon different from the metal or metal alloy surface finish on the bonding areas. Disclosed metal traces thus provide both a contact pad and an electrical connection to the contact pad.

Disclosed package substrates can be used for fine-pitch flip chip bonding, which has been found to help prevent solder beading/wicking causing shorting between adjacent metal traces, such as due to underfill voiding. However, disclosed package substrates can also be applied to coarse pitch flip chip bonding.

### BRIEF DESCRIPTION OF THE DRAWINGS

Reference will now be made to the accompanying drawings, which are not necessarily drawn to scale, wherein:

FIG. 1A is a cross-sectional depiction an example package substrate having metal traces that include a bonding area having a base metal and a metal or metal alloy surface finish thereon for bonding of bonding features of an IC die thereto, and an interconnect trace portion on both sides of the bonding area including the base metal having a surface finish thereon different from the metal or metal alloy surface finish, according to an example embodiment.

FIG. 1B is a cross-sectional depiction an example packaged semiconductor device having an IC die having pillars bonded to the bonding area of a trace of the package substrate shown in FIG. 1A having solder balls added to the bottom side of the package substrate, according to an example embodiment.

FIG. 2A is a top view of an example package substrate having metal traces that include a bonding area having a base metal and a metal or metal alloy surface finish thereon for bonding of bonding features on an IC die thereto, and an interconnect trace portion on both sides of the bonding area including the base metal having a surface finish thereon different from the metal or metal alloy surface finish, according to an example embodiment.

FIG. 2B is an example cross section depiction of one of the traces in FIG. 2A within the bonding area, FIG. 2C is an example cross section depiction of one of the traces in FIG. 2A in the interconnect trace portion, while FIG. 2D is another example cross section depiction of one of the traces in FIG. 2A in the interconnect trace portion, according to various example embodiments.

FIGS. 3A and 3B are a cross-sectional view and a top view, respectively, of an example package substrate having metal traces with solder resist between the traces, where the traces include a bonding area having a base metal and a metal or metal alloy surface finish thereon for bonding of bonding features on an IC die thereto, and an interconnect trace portion on both sides of the bonding area including the base metal having a surface finish thereon different from the metal or metal alloy surface finish, according to another example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

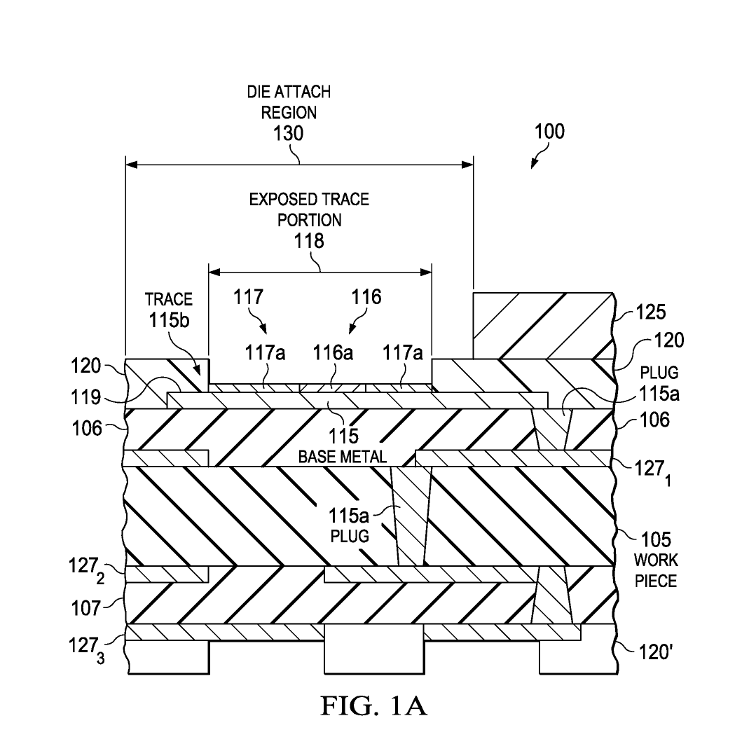

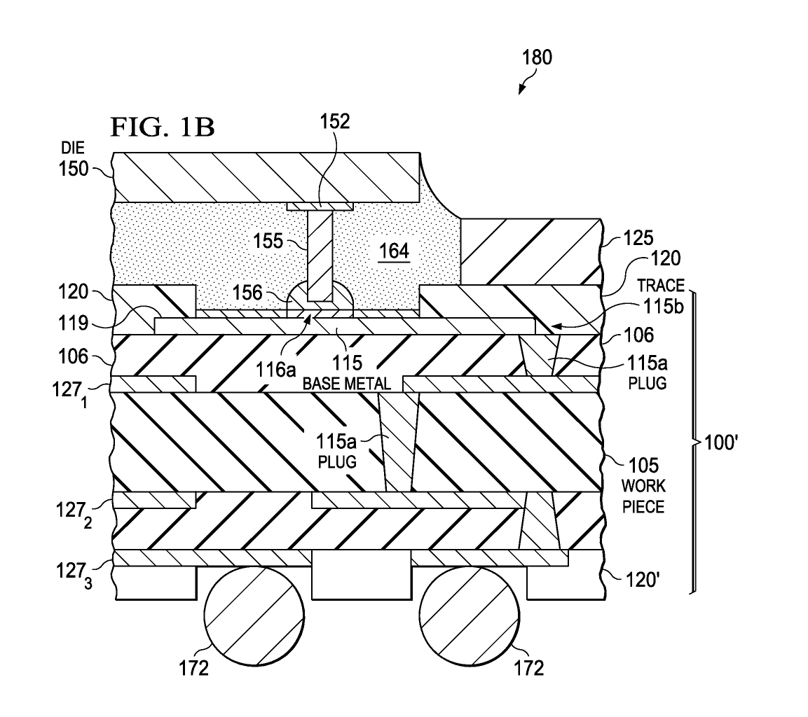

FIG. 1A is a cross-sectional depiction an example package substrate 100 having metal traces 115b that include a bonding area 116 having a base metal 115 and a metal or metal alloy surface finish thereon 116a for bonding of bonding features on an IC die thereto, and an interconnect trace portion 117 on both sides of the bonding area including the base metal 115 having a second surface finish 117a thereon different from the metal or metal alloy surface finish, according to an example embodiment. Package substrate 100 shown as a multi-level (ML) printed circuit board (PCB) including a plurality of alternating metal and dielectric layers including a dielectric core (base material) workpiece 105, bottom side dielectric layer 107 and a top dielectric layer 106 on the top side of the workpiece 105, with a top metal layer identified as base metal layer 115 on the top dielectric layer 106. Embedded metal layers 127₁, 127₂, and a bottom side metal layer 127₃ are also shown. Filled through-vias in the workpiece 105 shown as metal plugs 115a together with metal traces associated with embedded metal layers 127₁, 127₂ and 127₃ provide an electrical connection from the bonding area 116 on the top side of the workpiece 105 to the bottom side of the workpiece 105. Solder mask 120′ is shown on a portion of the bottom side metal layer 127₃. Although package substrate 100 is shown being an ML structure, disclosed embodiments include single dielectric package substrate structures where the workpiece 105 provides the top dielectric layer 106.

Base metal layer 115 which comprises a metal or metal alloy material (e.g., copper or copper alloy) provides a plurality of metal traces 115b on a surface of the top dielectric layer 106. A first solder resist layer 120 provides covered trace portions 119 for the plurality of metal traces 115b.

A second solder resist layer 125 is shown on the first solder resist layer 120 defining an inner die attach region 130. Inner die attach region 130 is recessed relative to the second solder resist layer 125. The inner die attach region 130 includes exposed trace portions 118 of the plurality of metal traces 115b within. The exposed trace portions 118 each include a bonding area 116 and an interconnect trace portion 117 on both sides of the bonding area 116.

Surface finish 116a is generally a plated layer on base metal 115 and can comprise solder (Sn comprising), or other metal or metal alloy layer such as Ni/Au that facilitate soldering thereto. Second surface finish is on base metal 115 in interconnect trace portions 117, and comprises a material different from the metal or metal alloy surface finish 116a. Second surface finish 117a is selected to be a material that does not wet solder.

For example, second surface finish 117a can comprise a dielectric, or an electrical conductive layer. In one embodiment, the second surface finish 117a is formed by a direct selective formation process that selectively chemically converts an exposed surface of base metal 115 when the base metal comprises an oxidizable metal (e.g. copper) to form a roughened non-solder wettable second surface finish 117a, while the surface finish 116a over bonding areas 116 can comprise a non-oxidizable material that does not react during the chemical conversion process. In the case of a noble metal comprising surface finish 116a over bonding areas 116, the noble metal generally remains unreacted by the selective formation processing. In addition, in the case of a solder comprising surface finish 116a over bonding areas 116, the solder comprising layer generally also remains unreacted by the selective formation processing. In either case, the solder resist layers 120 and 125 outside of the exposed trace portion 118 also generally remains unchanged by the second surface finish 117a selective formation process.

As noted above, the second surface finish 117a can also comprise a dielectric, such as certain silanes. Suitable silanes can include, but are not generally limited to, Dow-Corning Z-6040, 3-glycidoxypropyltrimethoxysilane, Dow-Corning Z-6032, N-2(vinylbenzylamino)-ethyl-3-aminopropyltrimethoxysilane, cationic styrylamine trimethoxysilane, Dow-Corning Z-6020, aminoethylaminopropyltrimethoxysilane, Dow-Corning Z-6030, 3-methacryloxypropyltrimethoxysilane, and Dow-Corning Z-6011, 3-aminopropyltriethoxysilane. These materials can be suitably applied according to the manufacturer's instructions. These silane coupling agents are available from Dow Corning Corporation (Dow Corning Corporate Center, P.O. Box 994, Midland, Mich. 48686-0994).

Other suitable commercially available processes for forming the second surface finish 117a include known copper oxide deposition processes such as the Shipley reduced oxide process, “PRO BOND-80, available from Shipley Company L.L.C., (455 Forest Street, Marlborough, Mass. 01752), or the copper surface roughness enhancement process known as “BONDFILM™”, available from Atotech USA Inc., (500 Science Park Road, State College, Pa., 16801.

Regarding the “BONDFILM™” process in the case of copper, from the standpoint of the chemical process, the copper layer undergoes a combination of micro-roughening and treatment to form an organo-metallic layer on its surface. The “BONDFILM™” process utilizes a conveyorized machine that microetches the copper to depth of about 1.2 to 1.5 μm, while simultaneously converting the copper at the surface (about 200-300 Angstroms) to the desired organo-metallic structure. The visible result is generally a homogenous medium-brown color. Although BONDFILM™ is known for providing enhanced chemical and mechanical bonding of a copper surface with prepreg material during lamination of multilayer boards, BONDFILM™ and related processes are believed to be unknown for uses as described herein including as a second surface finish 117a for providing a non-solder wettable surface.

FIG. 1B is a cross-sectional depiction an example packaged semiconductor device 180 comprising an IC die 150 having pillars 155 with solder caps 156 on bond pads 152 bonded to the bonding area 116 of a metal trace 115b of the package substrate 100 shown in FIG. 1A having solder balls 172 added to the bottom of the package substrate shown in FIG. 1B as 100′, according to an example embodiment. Underfill 164 fills the gap between IC die 150 and the package substrate 100′. Pillar 155 can be replaced by other bonding features such as solder balls, or studs for the flip-chip assembly shown in FIG. 1B, or face-up assembly in the case of through-substrate via (TSV) die having bottomside TSV bonding features, such as protruding TSV tips in one particular embodiment.

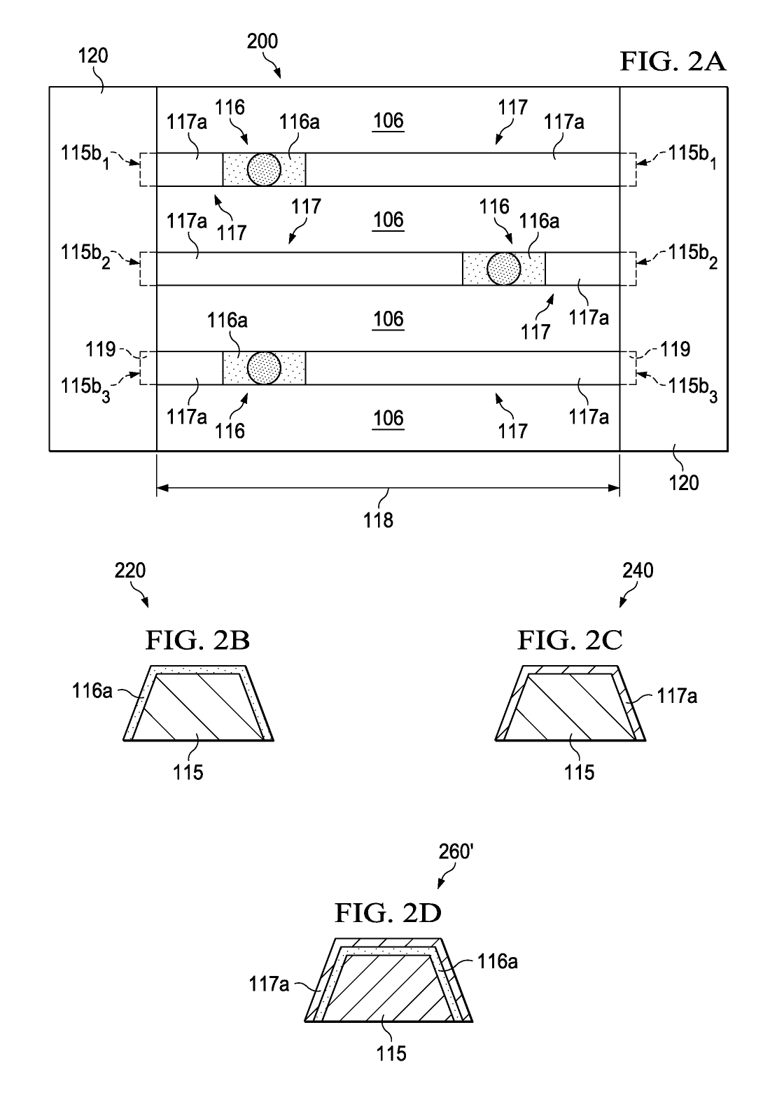

FIG. 2A is a top view of an example package substrate 200 having metal traces 115b₁, 115b₂, 115b₃ that include a bonding area 116 having a base metal 115 and a metal or metal alloy surface finish 116a thereon for bonding of bonding features on an IC die thereto, and an interconnect trace portion 117 on both sides of the bonding area 116 including the base metal having a surface finish thereon different from the metal or metal alloy surface finish, according to an example embodiment. The circular shapes within the bonding areas 116 represent where a pillar, such as pillar 155 shown in FIG. 1B, will make contact to bonding area 116. The plurality of metal traces 115b₁, 115b₂, 115b₃ can be positioned to provide a spacing of less than (<) 100 μm.

FIG. 2B is a cross section depiction of one of the traces 115b₁, 115b₂, or 115b₃ in FIG. 2A within the bonding area 116 shown as 220 and FIG. 2C a cross section depiction of one of the traces 115b₁, 115b₂, 115b₃ in FIG. 2A in the interconnect trace portion 117 shown as 240, according to example embodiments. Bonding area 116 shown in FIG. 2B includes a metal or metal alloy surface finish 116a on base metal 115, while interconnect trace portion 117 is shown in FIG. 2C includes a second surface finish 117a on base metal 115. FIG. 2D is another example cross section depiction of one of the traces in FIG. 2A in the interconnect trace portion shown as trace 260′, including second surface finish 117a on metal or metal alloy surface finish 116a on the base metal 115.

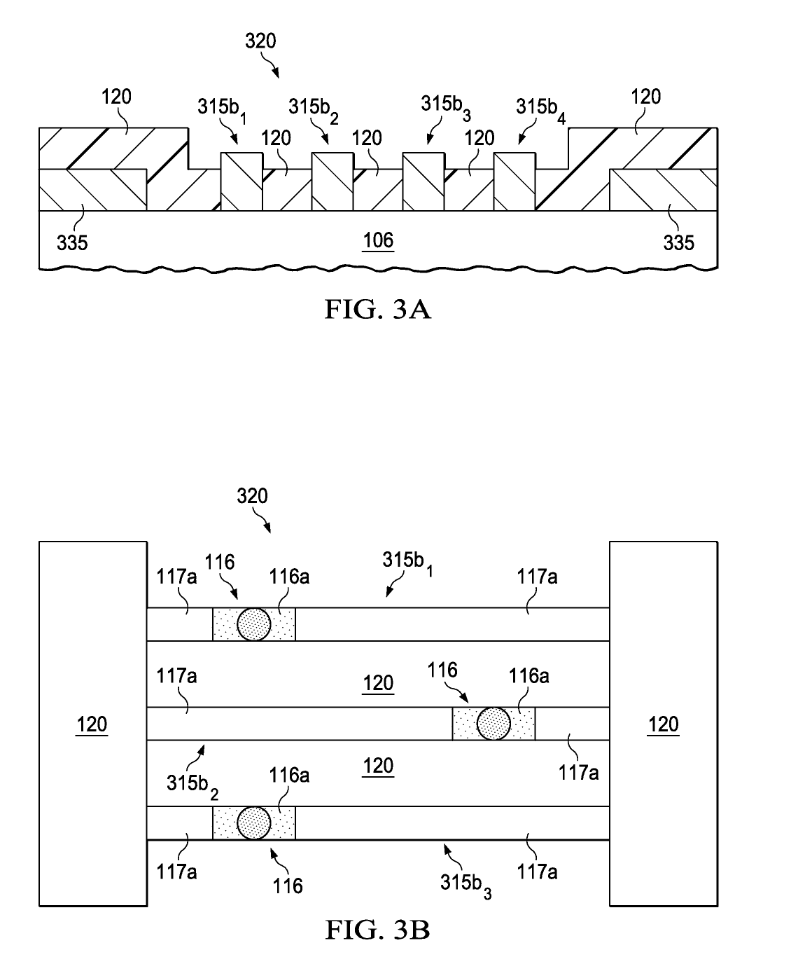

Disclosed embodiments also can be adapted to package substrates having “plugged” traces, which can be manufactured by filling the first solder resist layer 120 in-between the traces, or by drilling the traces after solder resist coating to exposure the metal or metal alloy surface finish 116a over the bonding areas 116. FIGS. 3A and 3B are a cross-sectional view and a top view, respectively, of an example package substrate 320 having metal traces with solder resist between the traces, where the traces include a bonding area having a base metal and a metal or metal alloy surface finish thereon for bonding of bonding features on an IC die thereto, and an interconnect trace portion on both sides of the bonding area including the base metal having a surface finish thereon different from the metal or metal alloy surface finish, according to another example embodiment. Through-vias are simply shown as pads 335 for simplicity, and the interconnect between the traces and the pads 335 are also not shown for simplicity. Traces in FIG. 3A are shown as 315b₁, 315b₂, 315b₃, and 315b₄, with traces 315b₁, 315b₂, 315b₃ being shown in FIG. 3B.

As described above, disclosed embodiments having traces with two different kinds of finish can solve industry-wide problems such solder wicking/bead, void and whiskering. Disclosed embodiments can also ease the underfill process, which can lead to a higher speed of bonding.

Disclosed embodiments can be integrated into a variety of assembly flows to form a variety of different packaged semiconductor devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

I claim:

1. A package substrate, comprising:
a workpiece;
at least a top dielectric layer and a metal layer on said workpiece which provides a plurality of metal traces on a surface of said top dielectric layer;
a first solder resist layer providing covered trace portions of said plurality of metal traces;
a second solder resist layer on said first solder resist layer defining an inner die attach region which is recessed relative to said second solder resist layer;
wherein said inner die attach region includes exposed trace portions of said plurality of metal traces, and wherein said exposed trace portions each include:
(i) a bonding area having a base metal and a metal or metal alloy surface finish thereon for bonding to bonding features of an integrated circuit (IC) die, and
(ii) an interconnect trace portion on both sides of the bonding area providing an electrical connection to the bonding area including the base metal having a second surface finish thereon different from said metal or metal alloy surface finish.

2. The package substrate of claim 1, wherein said metal or metal alloy surface finish comprises Sn or Ni and Au.

3. The package substrate of claim 1, wherein said second surface finish comprises a dielectric layer.

4. The package substrate of claim 1, wherein said metal or metal alloy surface finish comprises copper and said second surface finish comprises copper oxide.

5. The package substrate of claim 1, wherein said plurality of metal traces include a spacing less than (<) 100 μm.

6. The package substrate of claim 1, wherein said plurality of metal traces have said first solder resist layer therebetween.

7. A semiconductor device assembly, comprising:
an integrated circuit (IC) die having bonding features on its top side surface or bottom side surface, and
a package substrate, including:
a workpiece;
at least a top dielectric layer and a metal layer on said workpiece which provides a plurality of metal traces on a surface of said top dielectric layer;
a first solder resist layer providing covered trace portions of said plurality of metal traces;
a second solder resist layer on said first solder resist layer defining an inner die attach region which is recessed relative to said second solder resist layer;
wherein said inner die attach region includes exposed trace portions of said plurality of metal traces, and wherein said exposed trace portions each include:
(i) a bonding area having a base metal and a metal or metal alloy surface finish thereon for bonding to said bonding features of said IC die, and
(ii) an interconnect trace portion on both sides of the bonding area providing an electrical connection to the bonding area including the base metal having a second surface finish thereon different from said metal or metal alloy surface finish, and
an underfill material filling a space between said IC die and said package substrate.

8. The semiconductor device assembly of claim 7, wherein said metal or metal alloy surface finish comprises Sn or Ni and Au.

9. The semiconductor device assembly of claim 7, wherein said second surface finish comprises a dielectric layer.

10. The semiconductor device assembly of claim 7, wherein said metal or metal alloy surface finish comprises copper and said second surface finish comprises copper oxide.

11. The semiconductor device assembly of claim 7, wherein said plurality of metal traces include a spacing less than (<) 100 μm.

12. The semiconductor device assembly of claim 7, wherein said plurality of metal traces have said first solder resist layer therebetween.

13. The semiconductor device assembly of claim 7, wherein said bonding features comprise pillars which are flip-chip bonded to said package substrate.
